(19) United States
(12) Patent Application Publication
(10) Pub. No.: US 2026/0024727 A1
(43) Pub. Date: Jan. 22, 2026

(54) SEMICONDUCTOR MANUFACTURING APPARATUS AND METHOD FOR MANUFACTURING SEMICONDUCTOR DEVICE

(71) Applicants: Kioxia Corporation, Tokyo (JP); Tokyo Electron Limited, Tokyo (JP)

(72) Inventors: Kenichiro TORATANI, Yokkaichi Mie (JP); Kazuhiro MATSUO, Kuwana Mie (JP); Wakako MORIYAMA, Yokohama Kanagawa (JP); Kota TAKAHASHI, Yokkaichi Mie (JP); Masaya TODA, Yokkaichi Mie (JP); Ha HOANG, Yokkaichi Mie (JP); Shinji MORI, Nagoya Aichi (JP); Keiichi SAWA, Yokkaichi Mie (JP); Tomoki ISHIMARU, Yokkaichi Mie (JP); Yuya NAGATA, Nagoya Aichi (JP); Koji NEISHI, Nirasaki Yamanashi (JP); Masahisa WATANABE, Nirasaki Yamanashi (JP); Hironori YAGI, Nirasaki Yamanashi (JP); Shigeru NAKAJIMA, Nirasaki Yamanashi (JP)

(73) Assignees: Kioxia Corporation, Tokyo (JP); Tokyo Electron Limited, Tokyo (JP)

(21) Appl. No.: 19/071,853

(22) Filed: Mar. 6, 2025

(30) Foreign Application Priority Data
Jul. 17, 2024 (JP) 2024-114184

(51) Int. Cl. H01J 37/32; C23C 16/40; C23C 16/44; C23C 16/52; H01L 21/02

(52) U.S. Cl. CPC H01J 37/32449; C23C 16/407; C23C 16/4412; C23C 16/52; H01J 37/32834; H01L 21/02565; H01J 2237/24585; H01J 2237/332

(57) ABSTRACT

According to one embodiment, a semiconductor manufacturing apparatus includes a chamber that is used for deposition of an oxide film, a susceptor that is provided in the chamber and on which a substrate is placed, at least a supply pipe that supplies a gas to the chamber, an exhaust pipe that exhausts the gas from the chamber, and a controller that is configured to control supply of each of a first source gas, an oxidizing gas, a reducing gas activated by plasma, and a first halide gas activated by plasma to the chamber, and gas exhaust from the chamber.

### CROSS-REFERENCE TO RELATED APPLICATION

This application is based upon and claims the benefit of priority from Japanese Patent Application No. 2024-114184, filed Jul. 17, 2024, the entire contents of which are incorporated herein by reference.

### FIELD

Embodiments described herein relate generally to a semiconductor manufacturing apparatus and a method for manufacturing a semiconductor device.

### BACKGROUND

A chemical vapor deposition (CVD) apparatus is known as a semiconductor manufacturing apparatus. In the CVD apparatus, to shorten the downtime for chamber cleaning, dry cleaning is performed without opening the chamber to the atmosphere in some cases.

### BRIEF DESCRIPTION OF DRAWINGS

FIG. 1 is a configuration diagram of a semiconductor manufacturing apparatus according to a first embodiment.

FIG. 2 is a flowchart of a deposition process in the semiconductor manufacturing apparatus according to the first embodiment.

FIG. 3 is a conceptual diagram of a cleaning process in the semiconductor manufacturing apparatus according to the first embodiment.

FIG. 4 is a table showing binding energy between each element and oxygen.

FIG. 5 is a flowchart of the cleaning process in the semiconductor manufacturing apparatus according to the first embodiment.

FIG. 6 is a flowchart of the cleaning process in the semiconductor manufacturing apparatus according to the first embodiment.

FIG. 7 is a timing chart showing process conditions in the respective steps shown in FIGS. 5 and 6.

FIG. 8 is a configuration diagram of a semiconductor manufacturing apparatus according to a first example of a second embodiment.

FIG. 9 is a configuration diagram of a semiconductor manufacturing apparatus according to a second example of the second embodiment.

FIG. 10 is a flowchart of the cleaning process in a semiconductor manufacturing apparatus according to a third embodiment.

FIG. 11 is a flowchart of the cleaning process in the semiconductor manufacturing apparatus according to the third embodiment.

FIG. 12 is a configuration diagram of a semiconductor manufacturing apparatus according to a fourth embodiment.

FIG. 13 is a table showing binding energy between each of In, Ga, and Zn and halogen element.

FIG. 14 is a flowchart of the cleaning process in the semiconductor manufacturing apparatus according to the fourth embodiment.

FIG. 15 is a flowchart of the cleaning process in the semiconductor manufacturing apparatus according to the fourth embodiment.

FIG. 16 is a timing chart showing process conditions in the respective steps shown in FIGS. 14 and 15.

FIG. 17 is a configuration diagram of a semiconductor manufacturing apparatus according to a first example of a fifth embodiment.

FIG. 18 is a configuration diagram of a semiconductor manufacturing apparatus according to a second example of the fifth embodiment.

### DETAILED DESCRIPTION

In general, according to one embodiment, a semiconductor manufacturing apparatus includes a chamber that is used for deposition of an oxide film, a susceptor that is provided in the chamber and on which a substrate is placed, at least a supply pipe that supplies a gas to the chamber, an exhaust pipe that exhausts the gas from the chamber, and a controller that is configured to control supply of each of a first source gas, an oxidizing gas, a reducing gas activated by plasma, and a first halide gas activated by plasma to the chamber, and gas exhaust from the chamber.

In the description below, embodiments will be described with reference to the drawings. Note that, in the description below, components having substantially the same functions and configurations are denoted by the same reference numerals, and repetitive explanation is made where necessary. Further, each embodiment described below exemplifies an apparatus and a method for embodying the technical idea of the embodiment, and the embodiment does not limit the materials, shapes, structures, layout, and the like of the components to those described below.

### 1. First Embodiment

A semiconductor manufacturing apparatus according to a first embodiment is now described. In the following, a CVD apparatus for forming an oxide film will be described as a semiconductor manufacturing apparatus. An atomic layer deposition (ALD) apparatus for forming InGaZnO (Hereinafter also referred to as “IGZO”) including indium (In), gallium (Ga), zinc (Zn), and oxygen (O) will be described herein. Note that oxide film that is formed by the CVD apparatus is not limited to InGaZnO. Alternatively, oxide film that is formed by the CVD apparatus may be metal oxide film, conductive metal oxide film, or oxide semiconductor, but are not limited to these films. Also, the CVD apparatus is not limited to the ALD apparatus. For example, the CVD apparatus may be a low pressure chemical vapor deposition (LPCVD) apparatus, or may be a plasma CVD apparatus. Also, in the description below, dry cleaning that is performed without opening the chamber to the atmosphere will be simply referred to as “cleaning”.

### 1.1 Configuration

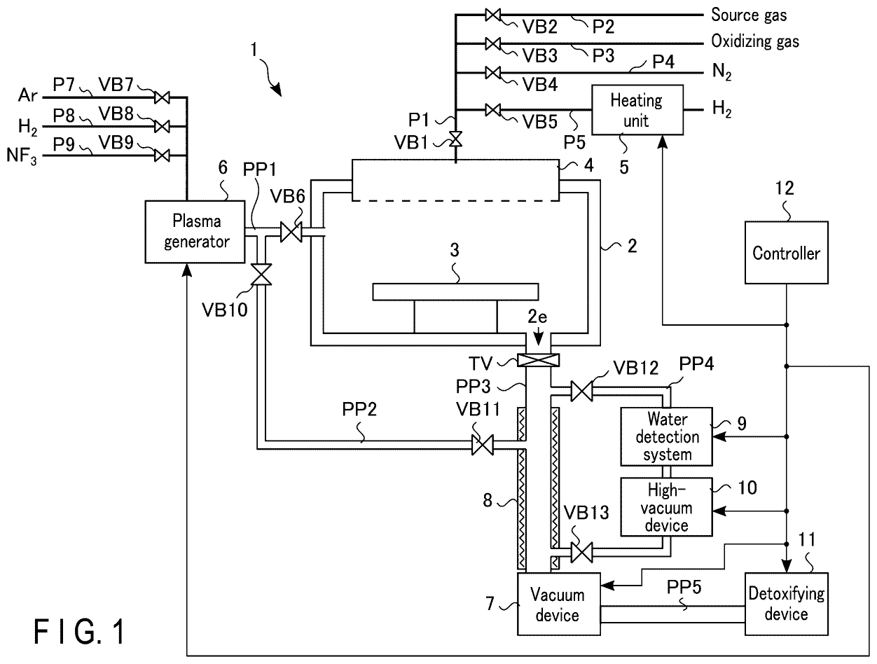

First, an example of a semiconductor manufacturing apparatus will be described with reference to FIG. 1. FIG. 1 is a configuration diagram of a semiconductor manufacturing apparatus 1. Note that, in the example in FIG. 1, some of the couplings between the components of the semiconductor manufacturing apparatus 1 are indicated by arrows, but the couplings between the components are not limited to this.

As shown in FIG. 1, the semiconductor manufacturing apparatus 1 includes a chamber 2, a susceptor 3, a showerhead 4, a heating unit 5, a plasma generator 6, a vacuum device 7, a pipe heater 8, a water detection system 9, a high-vacuum device 10, a detoxifying device 11, a controller 12, a throttle valve (or a butterfly valve) TV, valves VB1 to VB13, supply pipes P1 to P5 and P7 to P9, and pipes PP1 to PP5.

The chamber 2 is a processing chamber that is used for deposition. For example, an internal pressure of the chamber 2 is maintained at a low pressure (a lower pressure than atmospheric pressure). The chamber 2 has an exhaust port 2e for exhausting gas in the chamber 2. The chamber 2 can have a configuration in which a temperature of an inner wall of the chamber 2 can be raised and lowered with a temperature adjustment mechanism (a chiller or the like, for example) not shown in the drawing. For example, the chamber 2 is managed at an appropriate temperature to suppress adhesion of by-products to the inner wall of the chamber 2 in a deposition process and a cleaning process.

A semiconductor substrate is placed on the susceptor 3. For example, the chamber 2 has a gate valve (not shown). The semiconductor substrate is carried from an outside of the chamber 2 onto the susceptor 3 via the gate valve. Note that the susceptor 3 may have a mechanism for lifting up the semiconductor substrate. For example, the susceptor 3 is attached to a lower surface of the inner wall of the chamber 2. For example, a heater is provided inside the susceptor 3. A temperature of the susceptor 3 is managed based on process conditions for the deposition process and the cleaning process.

The showerhead 4 is used for gas diffusion. The showerhead 4 is attached to an upper portion of the chamber 2. More specifically, the showerhead 4 is disposed so that the lower surface for discharging gas faces the upper surface of the susceptor 3, that is, the semiconductor substrate placed on the susceptor 3. A gas inlet port is provided in an upper portion of the showerhead 4. On the lower surface of the showerhead 4, a plurality of holes for releasing gas are formed. In the example in FIG. 1, gases are supplied to the showerhead 4, that is, into the chamber 2, via the supply pipe P1 and the valve VB1. For example, a source gas is supplied to the showerhead 4 via the supply pipe P2, the valve VB2, the supply pipe P1, and the valve VB1. An oxidizing gas is supplied to the showerhead 4 via the supply pipe P3, the valve VB3, the supply pipe P1, and the valve VB1. For example, oxygen (O₂) or ozone (O₃) is supplied as the oxidizing gas. Nitrogen (N₂) is supplied to the showerhead 4 via the supply pipe P4, the valve VB4, the supply pipe P1, and the valve VB1. Hydrogen (H₂) is supplied to the showerhead 4 via the supply pipe P5, the valve VB5, the supply pipe P1, and the valve VB1. Note that a plurality of gases may be simultaneously supplied to the chamber 2. Further, to efficiently clean the showerhead 4, a heater may be provided in the showerhead 4.

Note that a plurality of source gas supply pipes P2 may be provided based on the types of source gases. For example, in the case of InGaZnO, an organic source containing In, an organic source containing Ga, and an organic source containing Zn are used as the source gases. In this case, three systems of the source gas supply pipe P2 and the valve VB2 are provided. More specifically, the supply pipe P2 and the valve VB2 corresponding to the organic source containing In, the supply pipe P2 and the valve VB2 corresponding to the organic source containing Ga, and the supply pipe P2 and the valve VB2 corresponding to the organic source containing Zn are provided. Further, the source gas supply pipe P2 may be heated by a heating mechanism (not shown). For example, in a case where the source gas is a vaporized gas of a liquid raw material, the supply pipe P2 may be heated at an appropriate temperature so as not to be liquefied in the pipe.

In the present embodiment, the heating unit 5 is provided on the upstream side of the valve VB5 in the H₂ supply pipe P5. The heating unit 5 is a unit (device) that heats H₂. That is, the heating unit 5 supplies a heated H₂ gas (Hereinafter also referred to as a “high-temperature H₂”) to the chamber 2. For example, the high-temperature H₂ is used for purging moisture in the chamber 2 in the cleaning process. By using the heating unit 5, it is possible to perform a purge with the high-temperature H₂, regardless of the temperature of the susceptor 3.

The plasma generator 6 is a device that causes plasma discharge outside the chamber 2. Hereinafter, a case where plasma discharge is caused will be also referred to as “putting plasma into an ON state”. The plasma generator 6 is also called a remote plasma device. The plasma generator 6 includes a chamber for causing plasma discharge therein. The plasma generator 6 activates a gas supplied to the plasma generator 6 by plasma, to generate radicals. Argon (Ar) is supplied to the plasma generator 6 via the supply pipe P7 and the valve VB7. For example, H₂ is supplied as a reducing gas to the plasma generator 6 via the supply pipe P8 and the valve VB8. For example, Nitrogen trifluoride (NF₃) is supplied as a cleaning gas to the plasma generator 6 via the supply pipe P9 and the valve VB9. Note that, as the cleaning gas (etching gas), a gas containing at least one halogen element such as fluorine (F), chlorine (Cl), bromine (Br), or iodine (I), which is a halide gas, may be used. More specifically, for example, at least one of F₂, HF, SF₆, BCl₃, Cl₂, HCl, ClF₃, Br₂, HBr, I₂, and HI may be used as the halide gas. For example, to suppress deposition of by-products due to thermal decomposition in an exhaust pipe PP3 or the like, the cleaning gas is preferably a material having a relatively high binding energy to the etching target. In this case, it is desirable to use plasma as an energy source for activating the cleaning gas.

The plasma generator 6 is coupled to the chamber 2 via a pipe PP1 and the valve VB6. Also, the plasma generator 6 is coupled to the exhaust pipe PP3 via the valve VB10, a bypass pipe PP2, and the valve VB11. For example, in a case where the gas (radical) activated by the plasma generator 6 is supplied to the chamber 2, the valve VB6 is opened, and the valve VB10 and the valve VB11 are closed. On the other hand, in a case where the gas (radical) activated by the plasma generator 6 is not supplied to the chamber 2, the valve VB6 is closed, and the valve VB10 and the valve VB11 are opened.

The exhaust pipe PP3 is coupled to the exhaust port 2e of the chamber 2 via the throttle valve TV. The throttle valve TV can adjust the degree of opening of the valve, and is used for controlling pressure in the chamber 2.

The exhaust pipe PP3 is coupled to the vacuum device 7. The vacuum device 7 exhausts the gas in the chamber 2 via the exhaust pipe PP3 and the throttle valve TV. A configuration of the vacuum device 7 is based on process conditions for the deposition process and the cleaning process. For example, the vacuum device 7 may have a configuration in which a mechanical booster pump is provided on the upstream side of the exhaust gas, and a dry pump is provided on the downstream side.

The pipe heater 8 is attached so as to cover the exhaust pipe PP3. The pipe heater 8 controls a pipe temperature of the exhaust pipe PP3. The exhaust pipe PP3 is managed at an appropriate temperature by the pipe heater 8, to suppress adhesion of by-products.

A bypass pipe PP4 is coupled to the exhaust pipe PP3 via the valve VB12 provided on the upstream of the exhaust pipe PP3 and the valve VB13 provided on the downstream side of the exhaust pipe PP3. The water detection system 9 and the high-vacuum device 10 are coupled to the bypass pipe PP4.

The water detection system 9 is a system that detects water contained in exhaust gas. For example, the water detection system 9 may include a Fourier transform infrared spectroscopy (FT-IR) analyzer or a non-dispersive infrared (NDIR) analyzer.

For example, in a case where moisture in exhaust gas is analyzed in the water detection system 9, the valves VB12 and VB13 are opened. Thus, part of the exhaust gas is introduced into the bypass pipe PP4.

The high-vacuum device 10 is a vacuum device having a higher degree of ultimate vacuum (lower pressure) than the vacuum device 7. For example, the high-vacuum device 10 is a turbo-molecular pump. For example, the high-vacuum device 10 can be used in a case where it is desired to exhaust the gas (and water) in the chamber 2 more efficiently.

The detoxifying device 11 is a device that removes substances (harmful substances) contained in the exhaust gas. The detoxifying device 11 is coupled to a gas discharge port of the vacuum device 7 via a pipe PP5. The detoxifying device 11 may be of a combustion type, a wet type, or a dry type.

The controller 12 controls the entire semiconductor manufacturing apparatus 1. More specifically, the controller 12 controls the susceptor 3, the heating unit 5, the plasma generator 6, the vacuum device 7, the pipe heater 8, the water detection system 9, the high-vacuum device 10, and the detoxifying device 11.

The controller 12 controls the throttle valve TV and the valves VB1 to VB13. Also, the controller 12 controls the amount of supply of each gas. Thus, the supply and exhaust of gas to and from the chamber 2 is controlled.

The controller 12 controls a gate valve (not illustrated), a semiconductor substrate transfer mechanism, and the like. Thus, transferring the semiconductor substrate into and out of the chamber 2 is controlled.

The controller 12 controls the entire semiconductor manufacturing apparatus 1, to perform the deposition process and the cleaning process.

For example, the valves VB1 to VB13 are air valves. Opening and closing is controlled by the controller 12.

### 1.2 Deposition Process

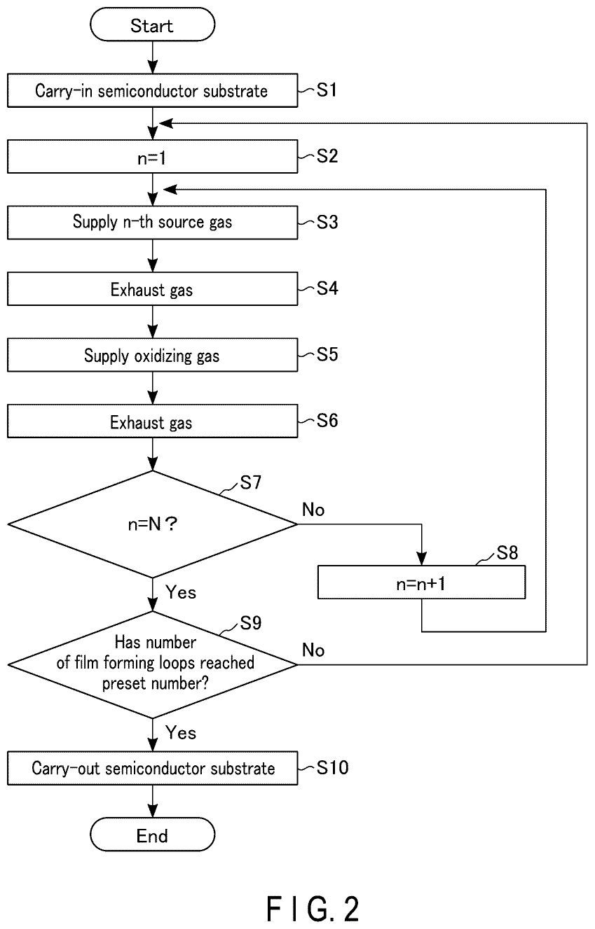

Next, an example of the deposition process in the semiconductor manufacturing apparatus 1 will be described with reference to FIG. 2. FIG. 2 is a flowchart of the deposition process.

As illustrated in FIG. 2, the controller 12 first carries a semiconductor substrate (also referred to as a “wafer”) into the chamber 2 (step S1). The semiconductor substrate is placed on the susceptor 3.

The controller 12 starts the deposition process in a state where the semiconductor substrate is on the susceptor 3. In the following, ALD using a plurality of source gases will be described, with InGaZnO being an example. In the description below, the total number of source gas types is N (N being an integer of 1 or greater). Each source gas is expressed as an n-th source gas with a variable n (n being an integer of 1≤n≤N). For example, in the case of InGaZnO, an organic source containing In, an organic source containing Ga, and an organic source containing Zn are used. Accordingly, N=3. For example, the organic source containing In is set as a first source gas (n=1). The organic source containing Ga is set as a second source gas (n=2). The organic source containing Zn is set as a third source gas (n=3). Note that the order of the first to third source gases may be changed.

The controller 12 sets the variable n=1 (step S2).

The controller 12 supplies the n-th source gas to the chamber 2 (step S3). For example, in a case where n=1, the organic source containing In is supplied. In a case where n=2, the organic source containing Ga is supplied. In a case where n=3, the organic source containing Zn is supplied. More specifically, the controller 12 opens the valve VB1 and the valve VB2 corresponding to the n-th source gas, and supplies the n-th source gas to the chamber 2. At this time, the controller 12 adjusts the throttle valve TV to control the pressure in the chamber 2. The exhaust gas is released into the vacuum device 7.

Next, the controller 12 stops supplying the n-th source gas, and exhausts the remaining source gas in the chamber 2 (step S4). More specifically, the controller 12 closes the valve VB1 and the valve VB2 corresponding to the n-th source gas, and stops supplying the n-th source gas to the chamber 2. In this state, the residual source gas in the chamber 2 is released into the vacuum device 7.

Next, the controller 12 supplies the oxidizing gas to the chamber 2 (step S5). More specifically, the controller 12 opens the valves VB1 and VB3, and supplies the oxidizing gas to the chamber 2. At this time, the controller 12 adjusts the throttle valve TV to control the pressure in the chamber 2. The exhaust gas is released into the vacuum device 7.

Next, the controller 12 stops supplying the oxidizing gas, and exhausts the remaining oxidizing gas in the chamber 2 (step S6). More specifically, the controller 12 closes the valves VB1 and VB3, and stops supplying the oxidizing gas to the chamber 2. In this state, the residual oxidizing gas in the chamber 2 is released into the vacuum device 7.

Next, the controller 12 checks whether the variable n has reached the total number N of source gas types (step S7).

If n=N is not satisfied (step S7_No), that is, if the variable n has not reached the total number N of source gas types, the controller 12 increments the variable n to satisfy n=n+1 (step S8). After that, the controller 12 proceeds to step S3.

If n=N is satisfied (step S7_Yes), that is, if the variable n has reached the total number N of source gas types, one deposition loop comes to an end. For example, a thin film (a layer of one to several molecules, for example) of InGaZnO for one deposition loop is formed on the semiconductor substrate.

Note that the supply of source gas is performed the same number of times for each gas of a plurality of source gases herein, but it is not limited to this. For example, the number of times of supply of the first source gas and the number of times of supply of the second source gas may be different.

Next, the controller 12 checks whether the number of deposition loops has reached a preset number (step S9). That is, a check is made to determine whether a thickness of the InGaZnO film has reached a target thickness.

If the number of deposition loops has not reached the preset number (step S9_No), the controller 12 proceeds to step S1. On the other hand, if the number of deposition loops has reached the preset number (step S9_Yes), the controller 12 ends the deposition process.

The controller 12 carries the semiconductor substrate out of the chamber 2 (step S10).

### 1.3 Cleaning Process

### 1.3.1 Outline of the Cleaning Process

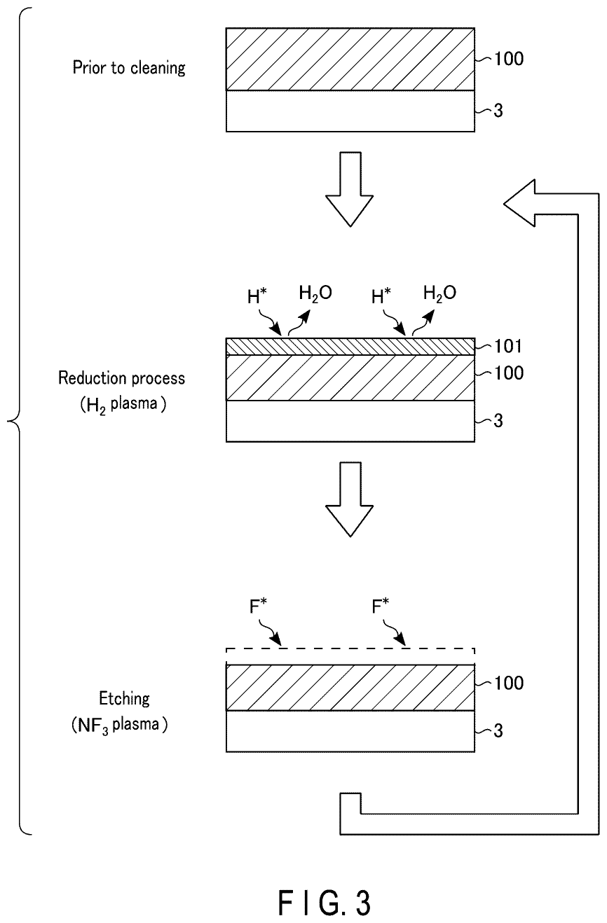

First, an outline of the cleaning process will be described with reference to FIG. 3. FIG. 3 is a conceptual diagram of the cleaning process.

As shown in FIG. 3, for example, after the deposition process of an oxide film 100, the oxide film 100 adheres to at least part of the surface of the susceptor 3 and the inner wall of the chamber 2. The cleaning process is performed to remove these pieces of the oxide film 100.

The cleaning process includes a reduction treatment process and an etching process. In the cleaning process, the controller 12 repeatedly executes a cleaning loop including the reduction treatment process and the etching process. That is, the reduction treatment process and the etching process are alternately and repeatedly performed.

The reduction treatment process is a process of reducing the surface of the oxide film 100 (a process of desorbing oxygen). More specifically, the plasma generator 6 generates H₂ plasma, to generate hydrogen radicals (H*, * representing radicals). The plasma generator 6 supplies the hydrogen radicals to the chamber 2. The hydrogen radicals bind to oxygen near the surface of the oxide film 100, to form water (H₂O) or OH. Water (or OH) is desorbed from the oxide film 100, and is discharged from the chamber 2. As a result, a modified layer 101 (from which oxygen has been desorbed) modified by the reduction treatment is formed on the surface of the oxide film 100. That is, the reduction treatment process is a process of forming the modified layer 101.

The etching process is a process of performing etching of the modified layer 101. More specifically, the plasma generator 6 generates NF₃ plasma, to generate fluorine radicals (F*). The plasma generator 6 supplies the fluorine radicals to the chamber 2. The modified layer 101 is subjected to etching with the fluorine radicals. The reduction treatment process (formation of the modified layer 101) and the etching process are repeatedly performed until the oxide film 100, formed on at least part of the surface of the susceptor 3 and the inner wall of the chamber 2, are removed.

### 1.3.2 Constituent Elements of the Oxide Film

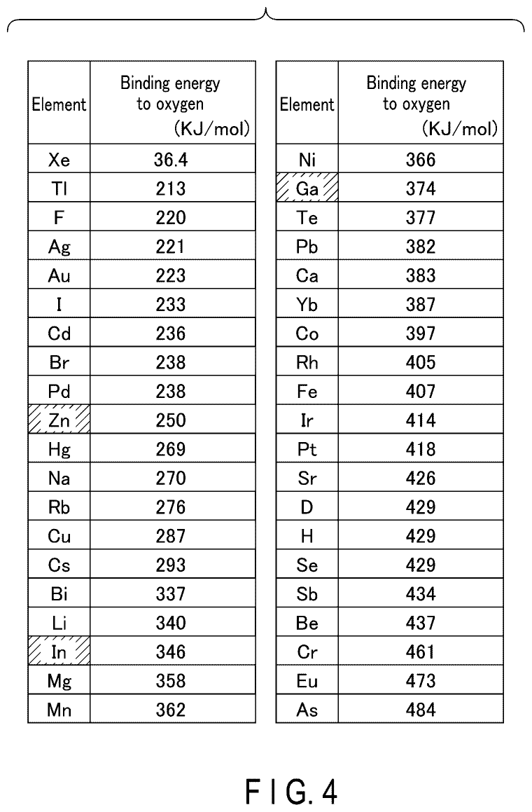

Next, an example of constituent elements of the oxide film on which the cleaning process of the present embodiment is to be performed will be described with reference to FIG. 4. FIG. 4 is a table showing binding energy between each element and oxygen.

The present embodiment can be applied to cleaning of an oxide film containing an element that has a relatively low binding energy to oxygen and is easily reduced by H₂ plasma (hydrogen radicals).

As shown in FIG. 4, an oxide film containing Ga and an element having a lower binding energy to oxygen than Ga is easily reduced by H₂ plasma. More specifically, the oxide film containing, as constituent elements, oxygen (O) and at least one element selected from xenon (Xe), thallium (Tl), fluorine (F), silver (Ag), gold (Au), iodine (I), cadmium (Cd), bromine (Br), palladium (Pd), zinc (Zn), mercury (Hg), sodium (Na), rubidium (Rb), copper (Cu), cesium (Cs), bismuth (Bi), lithium (Li), indium (In), magnesium (Mg), manganese (Mn), nickel (Ni), and gallium (Ga) is easily reduced.

For example, InGaZnO is an element in which any of In, Ga, and Zn as constituent elements is easily reduced, and is suitable as an application target film in the present cleaning process. Note that the oxide film to be subjected to the cleaning process is only required to contain an element having a low binding energy to oxygen, and is not limited to a conductive oxide film.

### 1.3.3 Flow of the Cleaning Process

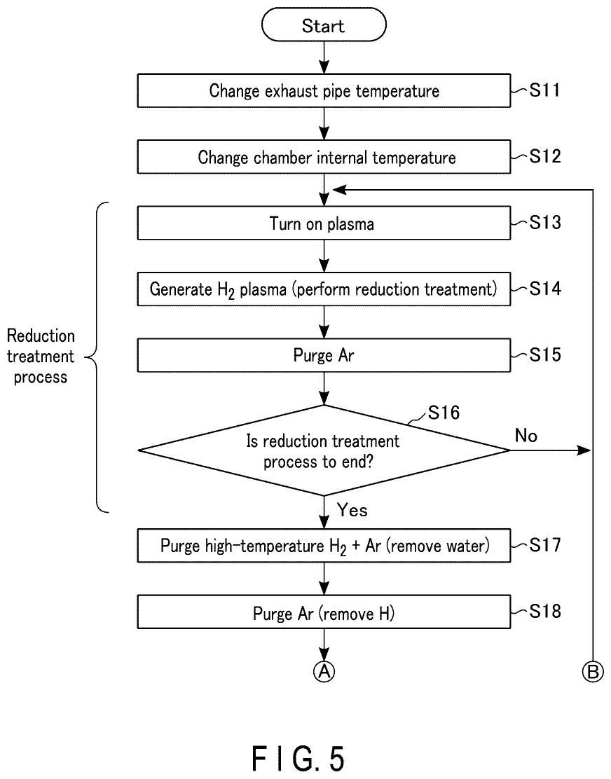

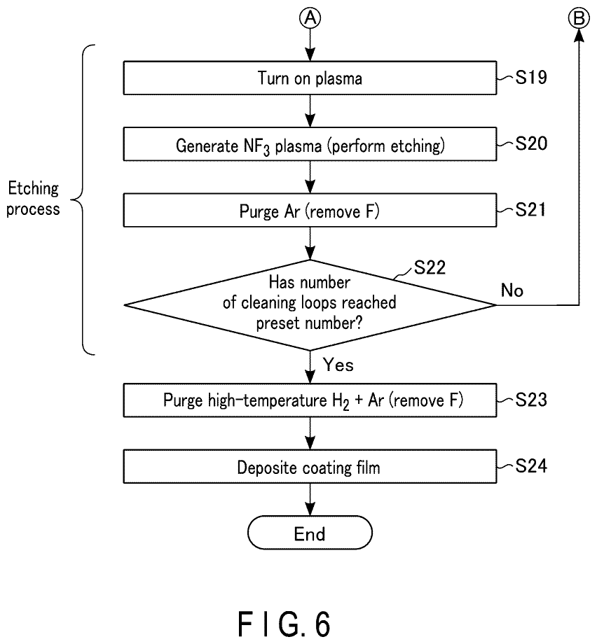

Next, an example of the cleaning process will be described with reference to FIGS. 5 to 7. FIGS. 5 and 6 show a flowchart of the cleaning process. With reference to the example in FIGS. 5 and 6, a case where a loop of a reduction treatment process including a reduction treatment and an Ar purge is repeatedly executed in the reduction treatment process will be described. For example, even in the same execution time of the reduction treatment process, water remaining in the chamber 2 can be effectively removed by repeating the reduction treatment and the purge at short intervals. Thus, re-adhesion of water to the oxide film 100 can be suppressed, and the reduction treatment for the oxide film can be performed more effectively. Note that the reduction treatment may be performed once or more.

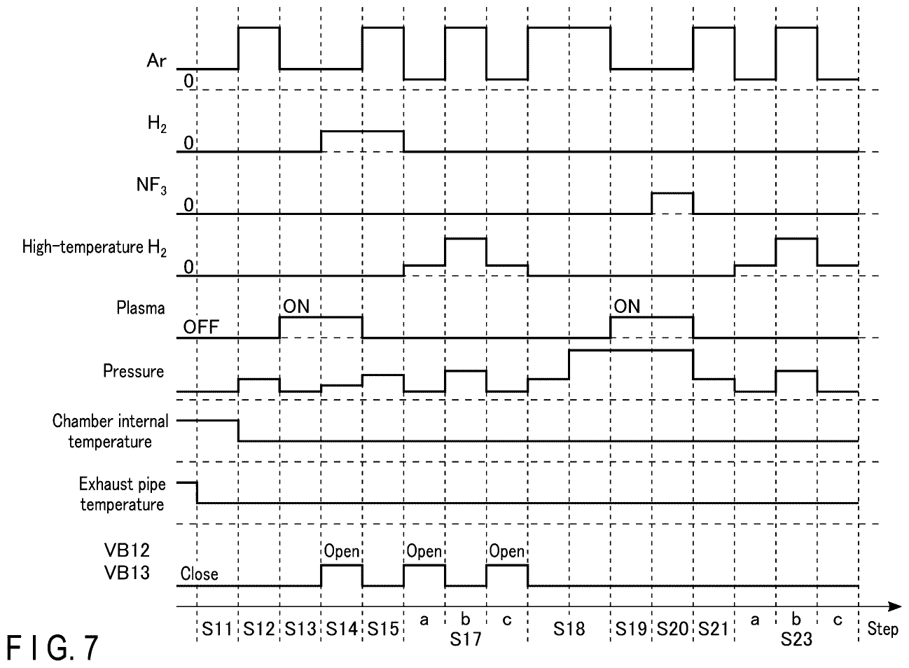

FIG. 7 is a timing chart showing process conditions in the respective steps shown in FIGS. 5 and 6. In FIG. 7, a vertical axis of each of Ar, H₂, NF₃, and high-temperature H₂ indicates a gas supply amount. Here, a scale of the vertical axis varies with gases. A vertical axis of plasma indicates whether the plasma is in an ON state or an OFF state in the plasma generator 6. A vertical axis of pressure indicates the pressure in the chamber 2. A vertical axis of a chamber internal temperature indicates the measured temperature in the chamber 2. For example, the chamber internal temperature is a temperature measured by a thermocouple installed on a wall of the chamber 2, or a temperature measured by a thermometer installed on the susceptor 3. For example, a vertical axis of an exhaust pipe temperature indicates measured temperature of the exhaust pipe PP3. Note that scales of the vertical axes of the chamber internal temperature and the exhaust pipe temperature are different each other. A vertical axis of VB12 and VB13 indicate whether the valve VB12 and the valve VB13 are in an open state or a closed state. Note that, in the example in FIG. 7, some steps are omitted.

### <S11>

In a case where the cleaning process is to be performed after the deposition process, the controller 12 first changes the temperature of the exhaust pipe PP3 as shown in FIG. 5. More specifically, the controller 12 changes the temperature of the exhaust pipe PP3 (the pipe heater 8) from a preset temperature of the deposition process to a preset temperature of the cleaning process. In the example in FIG. 7, the temperature of the exhaust pipe PP3 is lowered. For example, in the cleaning process, when the temperature of the exhaust pipe PP3 is relatively high, the exhaust gas including the modified layer 101 subjected to etching may be decomposed by the heat of the exhaust pipe PP3 and form a by-product in some cases. To suppress adhesion of by-products to the exhaust pipe PP3, the temperature of the exhaust pipe PP3 in the cleaning process can be set to a lower temperature than that in the deposition process. Note that, in a case where it is not necessary to change the temperature of the exhaust pipe PP3, this step can be omitted.

In the example in FIG. 7, Ar is supplied to the chamber 2. More specifically, the controller 12 opens the valves VB6 and VB7. In this state, the controller 12 supplies Ar to the chamber 2 via the plasma generator 6. Note that N₂ may be used, instead of Ar. In this case, the controller 12 opens the valves VB1 and VB4.

For example, the controller 12 sets the degree of opening of the throttle valve TV to 100%. Accordingly, the pressure in the chamber 2 is based on the flow rate of Ar.

### <S12>

As shown in FIG. 5, the controller 12 changes the chamber internal temperature. More specifically, the controller 12 changes a preset temperature of the heater in the susceptor 3 and/or the temperature adjustment mechanism (a chiller) that adjusts the temperature of the inner wall of the chamber 2 from the preset temperature of the deposition process to the preset temperature of the cleaning process. In the example in FIG. 7, the chamber internal temperature is lowered. The heat capacities of the susceptor 3 and the chamber 2 are larger than that of the exhaust pipe PP3. Therefore, the time length for temperature stabilization in step S12 can be longer than the time length for temperature stabilization in step S11. For example, stabilization of the chamber internal temperature might take several tens of minutes to several hours in some cases. Note that, in a case where it is not necessary to change the chamber internal temperature, this step can be omitted. Further, step S11 and step S12 may be executed simultaneously, or step S12 may be executed first.

In the example in FIG. 7, the flow rate of Ar is increased from that in step S11, for the purpose of removing dust in the chamber 2. Note that N₂ may be used, instead of Ar. For example, the controller 12 sets the degree of opening of the throttle valve TV to 100%. Accordingly, the pressure in the chamber 2 is increased based on the increase in the flow rate of Ar.

### <S13>

Steps S13 to S16 correspond to the reduction treatment process.

As shown in FIG. 5, the plasma generator 6 puts plasma into the ON state. Step S13 is a step for stabilizing plasma discharge. In the example in FIG. 7, the flow rate of Ar is smaller than the flow rate of Ar in step S12. The controller 12 adjusts the flow rate of Ar to a flow rate suitable for plasma discharge. In this state, the plasma generator 6 puts plasma into the ON state.

For example, the controller 12 sets the degree of opening of the throttle valve TV to 100%. Accordingly, the pressure in the chamber 2 is decreased based on the decrease in the flow rate of Ar.

### <S14>

As shown in FIG. 5, the plasma generator 6 generates H₂ plasma. Thus, the reduction treatment is performed. Specifically, as shown in FIG. 7, the plasma generator 6 maintains the plasma in the ON state. In this state, the controller 12 opens the valves VB6, VB7, and VB8, and supplies Ar and H₂ to the plasma generator 6. As a result, the plasma generator 6 generates H₂ plasma. The plasma generator 6 generates hydrogen radicals by the H₂ plasma. The plasma generator 6 supplies the hydrogen radicals (that is, the hydrogen activated by the plasma) to the chamber 2. As a result, the reduction treatment is performed, and the modified layer 101 is formed. Water generated in the chamber 2 by the reduction treatment is released into the vacuum device 7 via the exhaust pipe PP3. At this time, the controller 12 opens the valves VB12 and VB13. The controller 12 more efficiently removes water from the chamber 2, using the high-vacuum device 10. By using the high-vacuum device 10, re-adhesion of water to the oxide film 100 in the chamber 2 is suppressed. Note that, for example, the controller 12 may add a step after step S14, and open the valves VB12 and VB13 in a state where the supply of Ar and H₂ is stopped.

The water detection system 9 detects water contained in the exhaust gas while the valves VB12 and VB13 are in the open state. The controller 12 may change the execution time length of the reduction treatment, that is, the time length of step S14, based on a detected value of water.

For example, the controller 12 sets the degree of opening of the throttle valve TV to 100%. Accordingly, the pressure in the chamber 2 is increased from that in step S13 as the supply of H₂ starts.

After completion of step S14, the plasma generator 6 stops the plasma discharge (puts the plasma into the OFF state).

### <S15>

As shown in FIG. 5, the controller 12 performs an Ar purge. As a result, water in the chamber 2 is purged. Specifically, as shown in FIG. 7, the controller 12 closes the valves VB12 and VB13 of the bypass pipe PP4. In this state, for example, the controller 12 increases the flow rate of the Ar to be supplied to the chamber 2. In the example in FIG. 7, H₂ continues to be supplied. For example, the controller 12 sets the degree of opening of the throttle valve TV to 100%. Accordingly, the pressure in the chamber 2 is increased with the increase in the flow rate of Ar. That is, the pressure in the chamber 2 in step S15 is higher than that in step S14.

Note that, the controller 12 may couple (bypass) the plasma generator 6 to the exhaust pipe PP3 using the bypass pipe PP2, without putting the plasma into the OFF state in the plasma generator 6. More specifically, the valve VB6 is closed, and the valves VB10 and VB11 are opened. In this case, a supply pipe for Ar may be coupled to the valve VB1 so that Ar is supplied to the chamber 2 via the valve VB1. Alternatively, the controller 12 may open the valves VB1 and VB4, and performs an N₂ purge.

### <S16>

As shown in FIG. 5, the controller 12 determines whether to end the reduction treatment process. For example, the determination by the controller 12 is based on the detected value of water detected by the water detection system 9, and the upper limit number of loops of the reduction treatment process. More specifically, for example, in a case where the detected value of water is equal to or more than the preset value, and the number of loops of the reduction treatment process has not reached the upper limit number, the controller 12 determines to execute a loop of the reduction treatment process again. That is, the controller 12 determines not to end the reduction treatment process (step S16_No). On the other hand, in a case where the detected value of water is smaller than the preset value, or where the detected value of water is equal to or greater than the preset value but the number of loops of the reduction treatment process has reached the upper limit number, the controller 12 determines to end the reduction treatment process (step S16_Yes).

If the controller 12 determines not to end the reduction treatment process (step S16_No), the controller 12 proceeds to step S13. That is, a loop of the reduction treatment process is executed again. Note that, in a case where the plasma generator 6 and the exhaust pipe PP3 are bypassed, the controller 12 proceeds to step S14, because the plasma generator 6 maintains the plasma in the ON state.

If the controller 12 determines to end the reduction treatment process (step S16_Yes), the controller 12 proceeds to step S17. Note that, in a case where the detected value of water is equal to or greater than the preset value but the number of loops of the reduction treatment process has reached the upper limit number, the controller 12 may proceed to the next step S17, for example, or may display an alarm on the monitor screen and end the cleaning process.

### <S17>

As shown in FIG. 5, the controller 12 performs a purge, using high-temperature H₂ and Ar. As a result, water remaining in the chamber 2 is removed. Specifically, as shown in FIG. 7, the plasma generator 6 puts the plasma into the OFF state. In this state, the controller 12 opens the valves VB6 and VB7, to supply Ar to the chamber 2. Further, the controller 12 opens the valves VB1 and VB5, to supply high-temperature H₂ to the chamber 2. In the example in FIG. 7, step S17 is further divided into three steps S17a to S17c.

The flow rates of Ar and high-temperature H₂ in step S17a are relatively low. For example, the controller 12 sets the degree of opening of the throttle valve TV to 100%. Accordingly, the pressure in the chamber 2 is based on the flow rates of Ar and high-temperature H₂. The controller 12 opens the valves VB12 and VB13. The controller 12 more efficiently removes water from the chamber 2, using the high-vacuum device 10.

In step S17b, the controller 12 increases the flow rates of Ar and high-temperature H₂. As the flow rates of Ar and high-temperature H₂ rise, the pressure in the chamber 2 is also increased. As the pressure in the chamber 2 is increased, water remaining in the chamber 2 can be more effectively removed. The controller 12 closes the valves VB12 and VB13.

In step S17c, the controller 12 decreases the flow rates of Ar and high-temperature H₂. As the flow rates of Ar and high-temperature H₂ are decreased, the pressure in the chamber 2 is decreased. The controller 12 opens the valves VB12 and VB13. The controller 12 more efficiently removes water from the chamber 2, using the high-vacuum device 10.

Note that, in step S17, the controller 12 may open the valve VB8, and further supply H₂.

### <S18>

As shown in FIG. 5, the controller 12 performs a purge in the chamber 2 and the plasma generator 6, using Ar. As a result, H₂ remaining in the chamber 2 and the plasma generator 6 is removed. For example, when NF₃ plasma is generated in a state where H₂ remains, HF is formed, and there is a possibility that a pipe or the like will be corroded. Therefore, the controller 12 removes remaining H₂ in the chamber 2 and the plasma generator 6 by the Ar purge before generating the NF₃ plasma. Specifically, as shown in FIG. 7, the controller 12 closes the valves VB1 and VB5, to stop the supply of high-temperature H₂. The controller 12 increases the flow rate of Ar. In this state, for example, the controller 12 adjusts the degree of opening of the throttle valve TV, to raise the pressure in the chamber 2. As a result, H₂ remaining in the chamber 2 and the plasma generator 6 can be effectively removed.

### <S19>

Steps S19 to S22 correspond to the etching process.

As shown in FIG. 6, the plasma generator 6 puts plasma into the ON state. Like step S13, step S19 is a step for stabilizing plasma discharge. Note that the pressure in the chamber 2 in step S19 is preferably higher than the pressure in the chamber 2 in step S13. For example, the reduction treatment is preferably performed at a relatively low pressure to suppress re-adhesion of water in the chamber 2, and etching is preferably performed at a higher pressure than that for the reduction treatment process to diffuse the etching gas into the chamber 2 (or fill the chamber 2 with the etching gas).

In the example in FIG. 7, to stabilize the plasma discharge in the plasma generator 6, the controller 12 decreases the flow rate of Ar, for example, to the same flow rate as that in step S13. In this state, the plasma generator 6 puts plasma into the ON state. The pressure in the chamber 2 is maintained at a relatively high pressure through control on the throttle valve TV, as in step S18.

### <S20>

As shown in FIG. 6, the plasma generator 6 generates NF₃ plasma. As a result, etching is performed. Specifically, as shown in FIG. 7, the plasma generator 6 maintains the plasma in the ON state. In this state, the controller 12 opens the valves VB6, VB7, and VB9, and supplies Ar and NF₃ to the plasma generator 6. As a result, the plasma generator 6 generates NF₃ plasma. The plasma generator 6 generates fluorine radicals through the NF₃ plasma. The plasma generator 6 supplies the fluorine radicals (that is, the halide gas activated by the plasma) to the chamber 2. As a result, the modified layer 101 is etched. The exhaust gas of the etching is released into the vacuum device 7 via the exhaust pipe PP3. The pressure in the chamber 2 is maintained at a relatively high pressure through control on the throttle valve TV, as in step S18.

After completion of step S20, the plasma generator 6 puts the plasma into the OFF state.

### <S21>

As shown in FIG. 6, the controller 12 performs an Ar purge. As a result, F in the chamber 2 and the plasma generator 6 is removed. Specifically, as shown in FIG. 7, the controller 12 closes the valve VB9, to stop the supply of NF₃. In this state, for example, the controller 12 increases the flow rate of the Ar to be supplied to the chamber 2. For example, the controller 12 sets the degree of opening of the throttle valve TV to 100%. Accordingly, the pressure in the chamber 2 is based on the flow rate of Ar.

### <S22>

As shown in FIG. 6, the controller 12 checks whether the number of cleaning loops has reached a preset number.

If the number of cleaning loops has not reached the preset number (step S22_No), the controller 12 proceeds to step S13. On the other hand, if the number of cleaning loops has reached the preset number (step S22_Yes), the controller 12 proceeds to step S23.

Note that the controller 12 may change the time lengths of the reduction treatment process (step S14) and the etching process (step S20) when repeating the cleaning loop. For example, to reduce damage to the chamber 2, the susceptor 3, and the like due to cleaning, the time lengths of the reduction treatment process and the etching process may be shortened every time the loop is repeated.

### <S23>

As shown in FIG. 6, the controller 12 performs a purge, using high-temperature H₂ and Ar. As a result, F remaining in the chamber 2 is removed. Specifically, as shown in FIG. 7, the plasma generator 6 maintains the plasma in the OFF state. In this state, the controller 12 opens the valves VB6 and VB7, to supply Ar to the chamber 2. Further, the controller 12 opens the valves VB1 and VB5, to supply high-temperature H₂ to the chamber 2. In the example in FIG. 7, step S23 is further divided into three steps S23a to S23c. As in steps S17a to S17c, the flow rates of Ar and high-temperature H₂ are varied in steps S23a to S23c. Note that, in step S23, the controller 12 closes the valves VB12 and VB13.

In step S23, the controller 12 may further open the valve VB8, and supply H₂.

### <S24>

As shown in FIG. 6, the controller 12 performs deposition of a coating film. The coating film is a film that protects the surface of the susceptor 3. For example, a silicon oxide film (SiO₂), alumina (Al₂O₃), or the like can be used as the coating film. Note that the semiconductor manufacturing apparatus 1 can have a component for forming the coating film. For example, the semiconductor manufacturing apparatus 1 may include a source gas supply line for the coating film, or may have a component for applying plasma to the chamber 2.

### 1.4 Effects According to the Present Embodiment

With the configuration according to the present embodiment, it is possible to provide a semiconductor manufacturing apparatus capable of removing an oxide film by dry cleaning. This effect is now described in detail.

For example, in a semiconductor manufacturing apparatus (a CVD apparatus) that forms a conductive metal oxide film on which it is difficult to perform etching with a halide gas like InGaZnO, the chamber is opened to the atmosphere, and wet cleaning is manually performed. As the chamber is opened to the atmosphere, downtime of the apparatus for the cleaning becomes longer. That is, the operation rate of the apparatus is decreased.

On the other hand, with the configuration according to the present embodiment, the semiconductor manufacturing apparatus can perform the reduction treatment and the etching in the cleaning process. Oxygen on the surface of the oxide film can be desorbed by the reduction treatment. That is, the oxide film can be modified. The modified layer can be removed by dry etching using a halide gas. Thus, it is possible to perform dry cleaning of the oxide film by repeating the reduction treatment process and the etching process in the cleaning process. As a result, the chamber can be cleaned without being opened to the atmosphere. Thus, downtime of the apparatus can be shortened. That is, the operation rate of the apparatus can be increased.

Further, the configuration according to the present embodiment can be applied to a semiconductor manufacturing apparatus that forms an oxide film containing Ga and an element having a lower binding energy to oxygen than that to Ga. Thus, the reduction treatment of the oxide film can be effectively performed with hydrogen radicals.

Note that the present embodiment is not limited to a semiconductor manufacturing apparatus that forms a conductive oxide film. It can be applied to a semiconductor manufacturing apparatus that forms an oxide film containing Ga and an element having a lower binding energy to oxygen than that to Ga.

### 2. Second Embodiment

Next, a second embodiment will be described. In the second embodiment, two examples will be described as example configurations of a semiconductor manufacturing apparatus 1. In the description below, differences from the first embodiment are mainly explained.

### 2.1 First Example

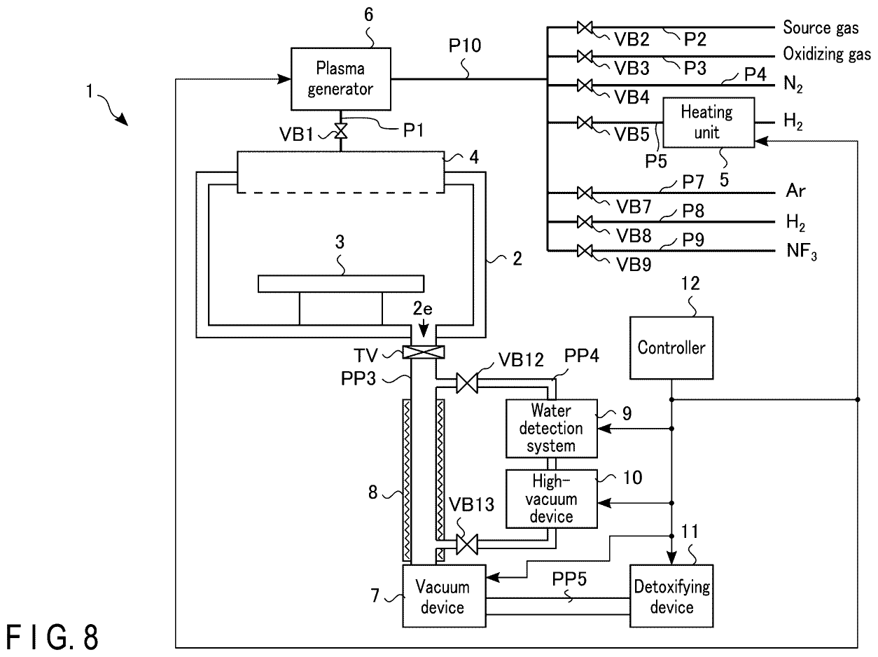

An example of a semiconductor manufacturing apparatus will be described with reference to FIG. 8. FIG. 8 is a configuration diagram of the semiconductor manufacturing apparatus 1.

As shown in FIG. 8, a plasma generator 6 is coupled to the upstream side of a supply pipe P1. The plasma generator 6 is coupled to a showerhead 4 via the supply pipe P1 and a valve VB1. Also, a supply pipe P10 is coupled to the plasma generator 6. A source gas, an oxidizing gas, N₂, high-temperature H₂, Ar, H₂, and NF₃ are supplied to the plasma generator 6 via the supply pipe P10. More specifically, the source gas is supplied to the plasma generator 6 via a supply pipe P2, a valve VB2, and the supply pipe P10. The oxidizing gas is supplied to the plasma generator 6 via a supply pipe P3, a valve VB3, and the supply pipe P10. N₂ is supplied to the plasma generator 6 via a supply pipe P4, a valve VB4, and the supply pipe P10. H₂ is supplied to the plasma generator 6 via a heating unit 5, a supply pipe P5, a valve VB5, and the supply pipe P10. Ar is supplied to the plasma generator 6 via a supply pipe P7, a valve VB7, and the supply pipe P10. H₂ is supplied to the plasma generator 6 via a supply pipe P8, a valve VB8, and the supply pipe P10. NF₃ is supplied to the plasma generator 6 via a supply pipe P9, a valve VB9, and the supply pipe P10. Each of the gases supplied to the plasma generator 6 is supplied to the chamber 2 via the supply pipe P1, the valve VB1, and the showerhead 4.

Accordingly, in this example, the source gas, the oxidizing gas, the reducing gas (H₂) and the halide gas (NF₃) activated by the plasma generator 6, and the like are supplied to the chamber 2 (showerhead 4) via the single supply pipe P1.

The valves VB6, VB10, and VB11, the pipe PP1, and the bypass pipe PP2 described in the first embodiment are not included in this example. Note that the bypass pipe PP2 may be provided so as to couple the plasma generator 6 to an exhaust pipe PP3. Further, the valve VB8 and the H₂ supply pipe coupled to the valve VB8 may be omitted. The other aspects of the configuration are the same as those of the first embodiment.

### 2.2 Second Example

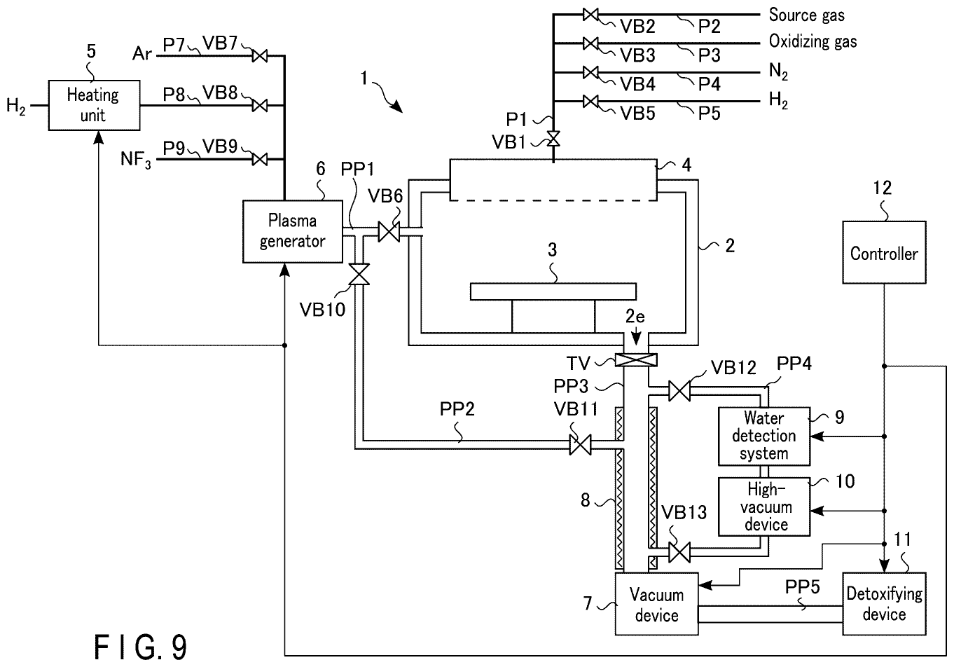

An example of a semiconductor manufacturing apparatus will be described with reference to FIG. 9. FIG. 9 is a configuration diagram of a semiconductor manufacturing apparatus 1.

As shown in FIG. 9, the heating unit 5 provided on the upstream side of the valve VB5 in FIG. 1 for the first embodiment is provided on the upstream side of the valve VB8. In this case, the valve VB5 and the H₂ supply pipe coupled to the valve VB5 may be omitted. The other aspects of the configuration are the same as those of the first embodiment.

### 2.3 Effects According to the Present Embodiment

With the configuration according to the present embodiment, the same effects as those of the first embodiment can be achieved.

Further, with the configuration according to the first example, the cleaning gas can be supplied to the showerhead 4. Thus, the oxide film adhering to the inside of the showerhead 4 can be removed.

Further, with the configuration according to the second example, high-temperature H₂ can be supplied to the plasma generator 6. Thus, a purge in the plasma generator 6 can be performed more efficiently.

### 3. Third Embodiment

Next, a third embodiment will be described. In the third embodiment, a process flow of cleaning different from that of the first embodiment will be described. In the description below, differences from the first embodiment are mainly explained.

### 3.1 Flow of the Cleaning Process

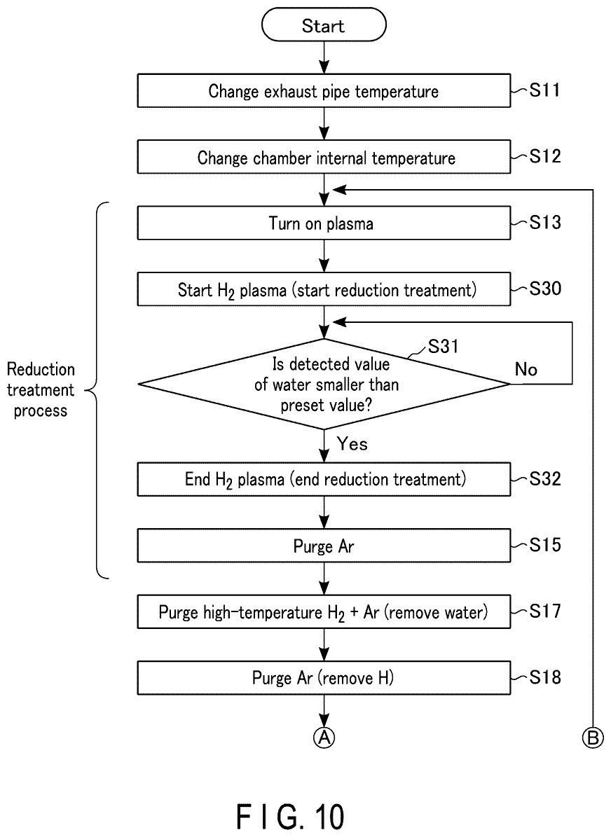

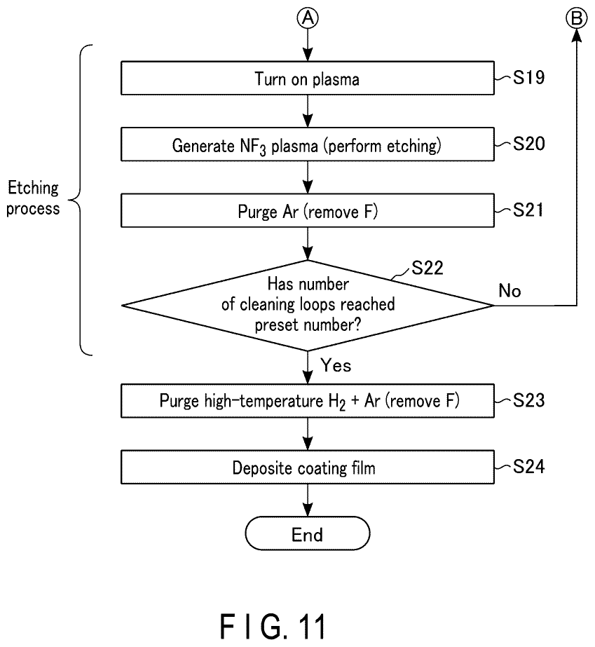

An example of the cleaning process will be described with reference to FIGS. 10 and 11. FIGS. 10 and 11 show a flowchart of a cleaning process.

As shown in FIG. 10, in step S13, a plasma generator 6 puts plasma into the ON state, as in the first embodiment.

### <S30>

As shown in FIG. 10, the plasma generator 6 starts discharging H₂ plasma. Thus, the reduction treatment is started. More specifically, the plasma generator 6 maintains the plasma in the ON state. In this state, a controller 12 starts supplying H₂ and Ar to the plasma generator 6 under the same conditions as in step S14 of the first embodiment. As a result, the plasma generator 6 starts discharging H₂ plasma. That is, the reduction treatment is started. At this time, a water detection system 9 starts detecting water contained in the exhaust gas.

### <S31>

As shown in FIG. 10, the water detection system 9 monitors water contained in the exhaust gas during the reduction treatment (during the discharge of H₂ plasma). Based on a detected value of water, the controller 12 determines whether to end the reduction treatment. The reduction treatment (discharge of H₂ plasma) is continued until the detected value of water falls below the preset value.

### <S32>

When the detected value of water falls below the preset value (step S31_Yes), the controller 12 ends the reduction treatment. That is, the plasma generator 6 puts the plasma into the OFF state. In the present embodiment, the water detection system 9 functions as a system for detecting an end point of the reduction treatment.

After completion of the reduction treatment, the controller 12 proceeds to step S15. When step S15 is completed, the controller 12 then proceeds to step S17. The steps thereafter are the same as those in the first embodiment.

### 3.2 Effects According to the Present Embodiment

With the configuration according to the present embodiment, the same effects as those of the first embodiment can be achieved.

Further, with the configuration according to the present embodiment, the water detection system 9 can be used as a system for detecting an end point of the reduction treatment. Thus, the time of the reduction treatment can be optimized.

Note that the present embodiment may be applied to the configuration according to the second embodiment.

### 4. Fourth Embodiment

Next, a fourth embodiment will be described. The fourth embodiment concerns a cleaning process including a plurality of etching processes using different cleaning gases containing different halogen elements. In the description below, differences from the first to third embodiments are mainly explained.

### 4.1 Configuration

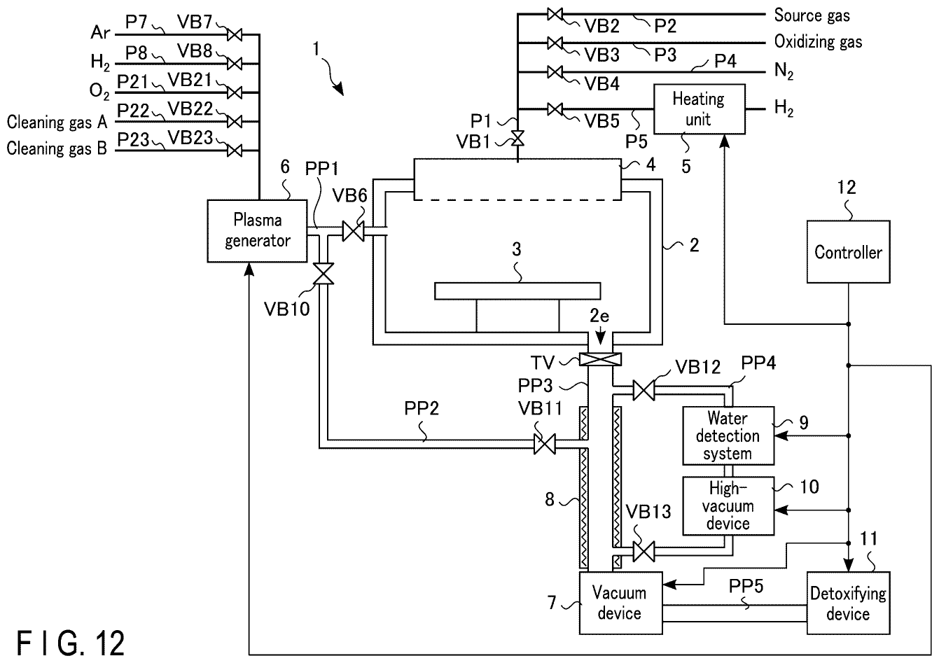

First, an example of a semiconductor manufacturing apparatus 1 will be described with reference to FIG. 12. FIG. 12 is a configuration diagram of the semiconductor manufacturing apparatus 1.

As shown in FIG. 12, Ar, H₂, and O₂, and two cleaning gases A and B are supplied to a plasma generator 6 of the present embodiment. The other aspects of the configuration are the same as those of the first embodiment in FIG. 1. Note that the number of cleaning gases is not limited to two. There may be three or more kinds of cleaning gases.

More specifically, Ar is supplied to the plasma generator 6 via a supply pipe P7 and a valve VB7. For example, H₂ is supplied as a reducing gas to the plasma generator 6 via a supply pipe P8 and a valve VB8. For example, O₂ is supplied as an oxidizing gas to the plasma generator 6 via a supply pipe P21 and a valve VB21. The cleaning gas A is supplied to the plasma generator 6 via a supply pipe P22 and a valve VB22. The cleaning gas B is supplied to the plasma generator 6 via a supply pipe P23 and a valve VB23.

The cleaning gases A and B are halide gases containing different halogen elements (F, Cl, Br, and I) from each other. For example, in a case where the cleaning gas A contains an iodine (I) element as a halogen element, the cleaning gas B contains at least one of fluorine (F), chlorine (Cl), and bromine (Br) excluding iodine (I) as a halogen element. For example, a halide gas containing fluorine (F) is F₂, HF, or SF₆. For example, a halide gas containing chlorine (Cl) is BCl₃, Cl₂, or HCl. For example, a halide gas containing fluorine (F) and chlorine (Cl) is ClF₃. For example, a halide gas containing bromine (Br) is HBr, Br₂, or BBr₃. For example, a halide gas containing iodine (I) is I₂ or HI. Note that any appropriate combination of halide gases may be selected as the cleaning gases A and B. For example, the cleaning gas A may contain iodine (I), and the cleaning gas B may contain chlorine (Cl). Alternatively, the cleaning gas A may contain chlorine (Cl), and the cleaning gas B may contain iodine (I).

In the cleaning process, the semiconductor manufacturing apparatus 1 according to the present embodiment performs a reduction treatment process, a first etching process using the cleaning gas A, and a second etching process using the cleaning gas B. The first and second etching processes will be described later in detail.

### 4.2 Binding Energy Between Each of In, Ga, and Zn and Halogen Element

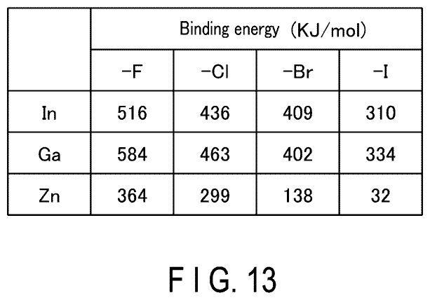

Next, the binding energy between each of In, Ga, and Zn and the halogen element will be described with reference to FIG. 13. In, Ga, and Zn are constituent elements of an oxide film (InGaZnO) to which the cleaning process of the present embodiment is to be applied. That is, In, Ga, and Zn are elements that are etching targets. FIG. 13 is a table showing binding energy between each of In, Ga, and Zn and the halogen element.

As shown in FIG. 13, as the magnitudes of the binding energies to In, Ga, and Zn are compared among the halogen elements, the relationship F>Cl>Br>I is established with any of In, Ga, and Zn. That is, iodine (I) has a lower binding energy to an etching target element than those of the other halogen elements. Therefore, in a case where InGaZnO is etched using a cleaning gas containing iodine (I) as the halogen element, the etching rate tends to be higher than that of a cleaning gas containing any of the other halogen elements. Accordingly, in a case where InGaZnO is etched using a cleaning gas containing iodine (I) as the halogen element, the etching time can be made shorter than that with a cleaning gas containing any of the other halogen element. Note that, since iodine (I) has a lower binding energy to an etching target element than those of the other halogen elements, etching by-products are likely to re-adhere to the chamber 2, the exhaust pipe PP3, and the like. Also, in a case where InGaZnO is etched using a cleaning gas containing fluorine (F) as the halogen element, the etching rate tends to be lower than that of a cleaning gas containing any of the other halogen elements. Note that, since fluorine (F) has a greater binding energy to an etching target element than those of the other halogen elements, etching by-products are unlikely to re-adhere to the chamber 2, the exhaust pipe PP3, and the like. As described above, etching characteristics (the etching rate, the by-products to be generated, the possibility of re-adhesion of the by-products, and the like) are different depending on the halogen element.

### 4.3 Cleaning Process

Next, a cleaning process will be described. The cleaning process according to the present embodiment includes a reduction treatment process, a first etching process, and a second etching process. In the cleaning process, the controller 12 repeatedly executes a cleaning loop including the reduction treatment process, the first etching process, and the second etching process.

The reduction treatment process is the same as that of the first embodiment.

The first etching process is a process of performing etching of a modified layer 101 using the cleaning gas A. In the plasma generator 6, radicals of a halogen element are generated using the cleaning gas A.

The second etching process is a process of performing etching of the modified layer 101 using the cleaning gas B. In the plasma generator 6, radicals of a halogen element are generated using the cleaning gas B. The second etching process is performed after the first etching process.

In the present embodiment, halide gases containing different halogen elements are used as the cleaning gases A and B, with attentions being paid to the aspect that etching characteristics are different depending on each halogen element. In a case where the etching time is to be preferentially shortened, for example, a halide gas containing iodine (I) is selected as the cleaning gas A. As the cleaning gas B, for example, a halide gas containing chlorine (Cl) is then selected. Further, in a case where re-adhesion of etching by-products is to be preferentially suppressed, for example, a halide gas containing chlorine (Cl) is selected as the cleaning gas A. As the cleaning gas B, for example, a halide gas containing iodine (I) is then selected. For example, the by-products re-adhering to the exhaust pipe PP3 and the like can be removed by the second etching process using a halide gas containing iodine (I).

In the following description of the present embodiment, a case where a halide gas containing iodine (I) is selected as the cleaning gas A, and a halide gas containing chlorine (Cl) is selected as the cleaning gas B is explained.

The cleaning loop including the reduction treatment process, the first etching process, and the second etching process is repeatedly executed until the oxide film 100, formed at least part of the surface of the susceptor 3 and on the inner wall of the chamber 2, are removed, as in the first embodiment.

### 4.4 Flow of the Cleaning Process

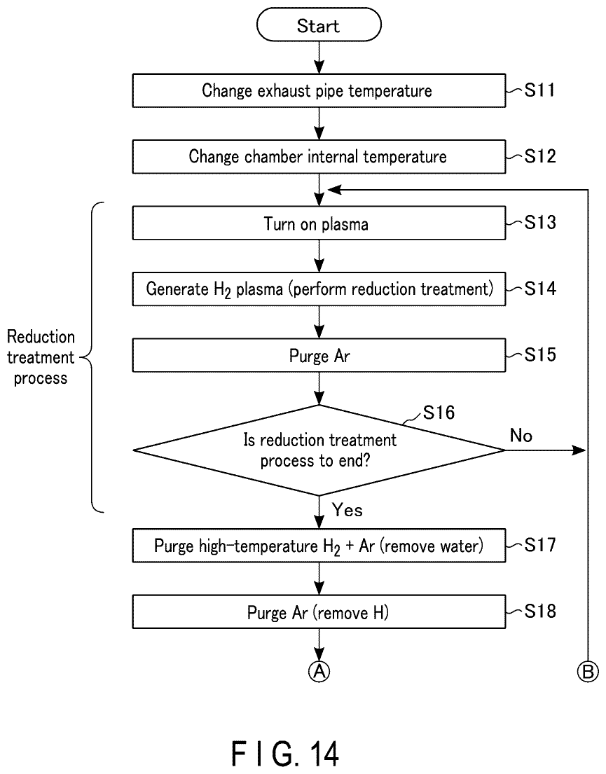

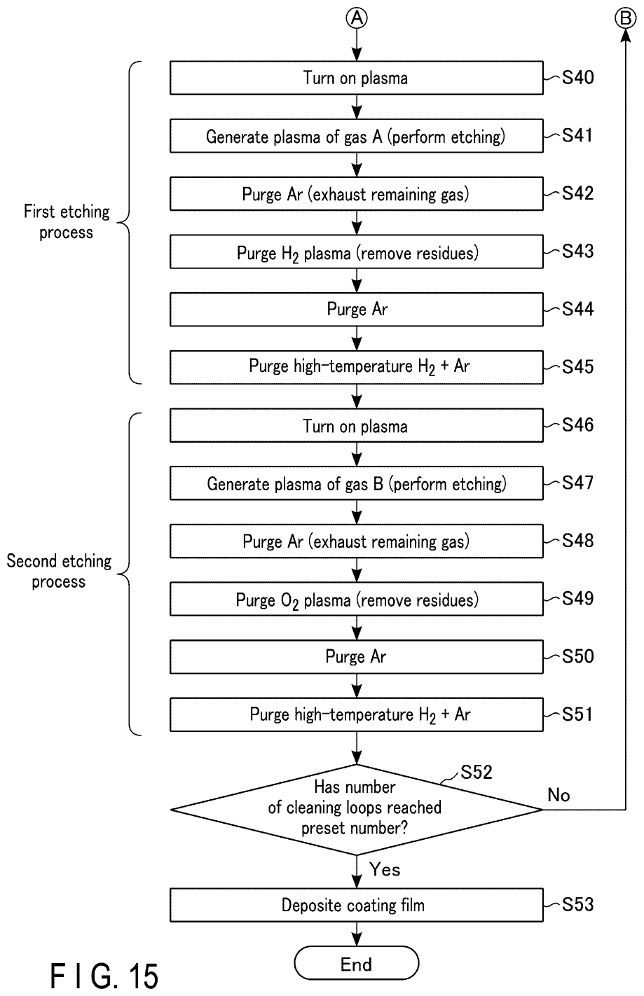

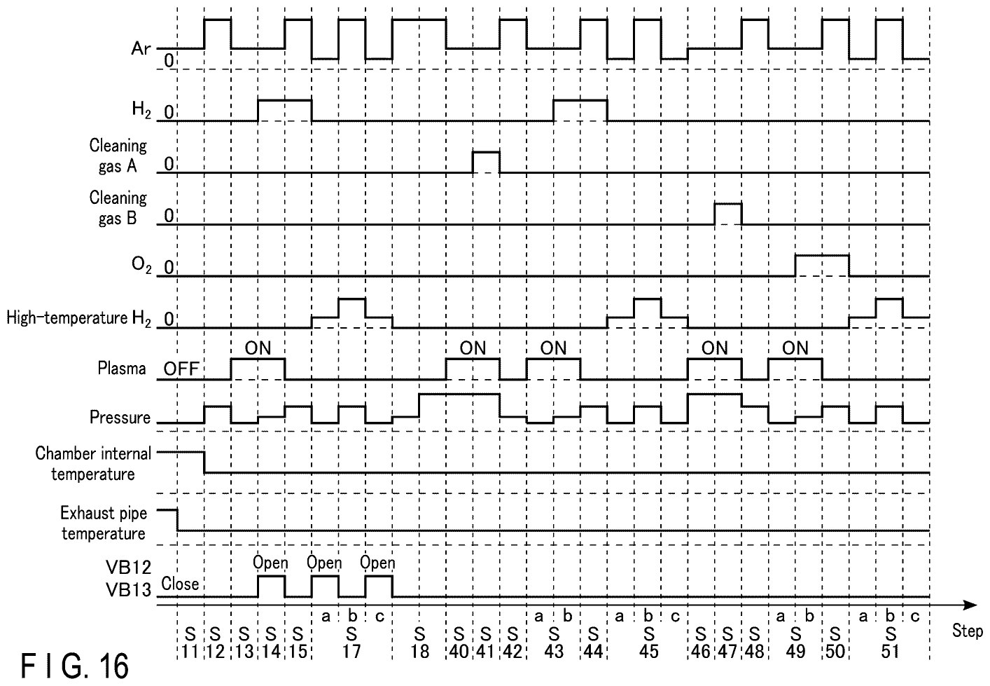

Next, an example of the cleaning process will be described with reference to FIGS. 14 to 16. FIGS. 14 and 15 show a flowchart of the cleaning process. FIG. 16 is a timing chart showing process conditions in the respective steps shown in FIGS. 14 and 15. In FIG. 16, a vertical axis of each of Ar, H₂, the cleaning gas A, the cleaning gas B, O₂, and high-temperature H₂ indicates a gas supply amount. Here, a scale of the vertical axis varies with gases. A vertical axis of plasma indicates whether the plasma is in the ON state or the OFF state in the plasma generator 6. A vertical axis of pressure indicates the pressure in the chamber 2. A vertical axis of a chamber internal temperature indicates a measured temperature in the chamber 2. Note that scales of the vertical axes of the chamber internal temperature and the exhaust pipe temperature are different each other. The vertical axis of VB12 and VB13 indicate whether the valve VB12 and the valve VB13 are in an open state or a closed state. Note that, in the example in FIG. 16, some steps are omitted.

### <S11> to <S18>

As shown in FIG. 14, the flow from step S11 to step S18 is the same as that described in the first embodiment with reference to FIG. 5. Steps S13 to S16 correspond to the reduction treatment process.

### <S40>

Steps S40 to S45 correspond to the first etching process.

As shown in FIG. 15, the plasma generator 6 puts plasma into the ON state after completion of step S18. Like step S13, step S40 is a step for stabilizing plasma discharge. Note that the pressure in the chamber 2 in step S40 is preferably higher than the pressure in the chamber 2 in step S13. For example, etching is preferably performed at a higher pressure than that for the reduction treatment process to diffuse the etching gas into the chamber 2 (or fill the chamber 2 with the etching gas).

In the example in FIG. 16, to stabilize the plasma discharge in the plasma generator 6, the controller 12 decreases the flow rate of Ar, for example, to the same flow rate as that in step S13. In this state, the plasma generator 6 puts plasma into the ON state. The pressure in the chamber 2 is maintained at a relatively high pressure through control on the throttle valve TV, as in step S18.

### <S41>

As shown in FIG. 15, the plasma generator 6 generates plasma of the cleaning gas A. As a result, etching is performed. Specifically, as shown in FIG. 16, the plasma generator 6 maintains the plasma in the ON state. In this state, the controller 12 opens the valves VB6, VB7, and VB22, and supplies Ar and the cleaning gas A to the plasma generator 6. As a result, the plasma generator 6 generates plasma of the cleaning gas A. The plasma generator 6 generates radicals of a halogen element with the plasma of the cleaning gas A. For example, in a case where the cleaning gas A contains iodine (I), radicals of iodine (I) are generated. The plasma generator 6 supplies the radicals of the halogen element (that is, the halide gas activated by the plasma) to the chamber 2. As a result, the modified layer 101 is etched. The exhaust gas of the etching is released into the vacuum device 7 via the exhaust pipe PP3. The pressure in the chamber 2 is maintained at a relatively high pressure through control on the throttle valve TV, as in step S18.

After completion of step S41, the plasma generator 6 puts the plasma into the OFF state.

### <S42>

As shown in FIG. 15, the controller 12 performs an Ar purge. As a result, the cleaning gas A remaining in the chamber 2 and the plasma generator 6 is exhausted. Specifically, as shown in FIG. 16, the controller 12 closes the valve VB22, to stop the supply of the cleaning gas A. In this state, for example, the controller 12 increases the flow rate of the Ar to be supplied to the chamber 2. For example, the controller 12 sets the degree of opening of the throttle valve TV to 100%. Accordingly, the pressure in the chamber 2 is based on the flow rate of Ar.

### <S43>

As shown in FIG. 15, the controller 12 performs a H₂ plasma purge, to remove residues in the chamber 2. Note that the plasma purge may be performed in a reducing atmosphere or in an oxidizing atmosphere. For example, in a case where the cleaning gas contains fluorine (F) or iodine (I), a plasma purge in the reducing atmosphere is preferable. For example, in the case of a plasma purge using H₂, hydrogen (H) binds to a halogen element, and is removed as HF, HI, HCl, HBr, or the like. In this example, since the cleaning gas A contains iodine (I), the H₂ plasma purge is adopted.

Specifically, as shown in FIG. 16, step S43 includes two steps S43a and S43b. In step S43a, the plasma generator 6 puts plasma into the OFF state. At this time, the controller 12 can control the flow rate of Ar and the pressure in the chamber 2 to the same levels as those with the reduction treatment process in step S13.

Next, in step S43b, the controller 12 further opens the valve VB8, and supplies Ar and H₂ to the plasma generator 6. As a result, the plasma generator 6 generates H₂ plasma. The plasma generator 6 generates hydrogen radicals through the H₂ plasma. The plasma generator 6 supplies the hydrogen radicals to the chamber 2. Thus, the plasma purge is performed.

### <S44>

As shown in FIG. 15, the controller 12 performs an Ar purge. Specifically, as shown in FIG. 16, the controller 12 performs the Ar purge, for example, under the same conditions as those in step S15.

### <S45>

As shown in FIG. 15, the controller 12 performs a purge, using high-temperature H₂ and Ar. Specifically, as shown in FIG. 16, the plasma generator 6 puts the plasma into the OFF state. In this state, the controller 12 opens the valves VB6 and VB7, to supply Ar to the chamber 2. Further, the controller 12 opens the valves VB1 and VB5, to supply high-temperature H₂ to the chamber 2. In the example in FIG. 16, step S45 is further divided into three steps S45a to S45c.

The flow rates of Ar and high-temperature H₂ in step S45a are relatively low. For example, the controller 12 sets the degree of opening of the throttle valve TV to 100%. Accordingly, the pressure in the chamber 2 is based on the flow rates of Ar and high-temperature H₂. Note that the controller 12 may open the valves VB12 and VB13 as in step S17a.

In step S45b, the controller 12 increases the flow rates of Ar and high-temperature H₂. As the flow rates of Ar and high-temperature H₂ are increased, the pressure in the chamber 2 is increased.

In step S45c, the controller 12 decreases the flow rates of Ar and high-temperature H₂. As the flow rates of Ar and high-temperature H₂ are decreased, the pressure in the chamber 2 is decreased. Note that the controller 12 may open the valves VB12 and VB13 as in step S17c.

Note that, in step S45, the controller 12 may open the valve VB8, and further supply H₂.

### <S46>

Steps S46 to S51 correspond to the second etching process.

As shown in FIG. 15, the plasma generator 6 puts plasma into the ON state after completion of step S45. As shown in FIG. 16, the processing conditions in step S46 are the same as those in step S40.

### <S47>

As shown in FIG. 15, the plasma generator 6 generates plasma of the cleaning gas B. As a result, etching is performed. Specifically, as shown in FIG. 16, the plasma generator 6 maintains the plasma in the ON state. In this state, the controller 12 opens the valves VB6, VB7, and VB23, and supplies Ar and the cleaning gas B to the plasma generator 6. As a result, the plasma generator 6 generates plasma of the cleaning gas B. The plasma generator 6 generates radicals of a halogen element with the plasma of the cleaning gas B. For example, in a case where the cleaning gas B contains chlorine (Cl), radicals of chlorine (Cl) are generated. The plasma generator 6 supplies the radicals of the halogen element (that is, the halide gas activated by the plasma) to the chamber 2. The pressure in the chamber 2 is maintained at a relatively high pressure through control on the throttle valve TV, as in step S41.

After completion of step S47, the plasma generator 6 puts the plasma into the OFF state.

### <S48>

As shown in FIG. 15, the controller 12 performs an Ar purge. As a result, the cleaning gas B remaining in the chamber 2 and the plasma generator 6 is exhausted. Specifically, as shown in FIG. 16, the controller 12 closes the valve VB23, to stop the supply of the cleaning gas B. In this state, for example, the controller 12 increases the flow rate of the Ar to be supplied to the chamber 2. For example, the controller 12 sets the degree of opening of the throttle valve TV to 100%. Accordingly, the pressure in the chamber 2 is based on the flow rate of Ar.

### <S49>

As shown in FIG. 15, the controller 12 performs an O₂ plasma purge, to remove residues in the chamber 2. For example, in a case where the residue removal (step S43) in the first etching process has been performed in a reducing atmosphere, the residue removal in the second etching process is performed in an oxidizing atmosphere, so that halogen elements that cannot be removed in the reducing atmosphere can be removed. For example, in the case of the plasma purge using O₂, fluorine (F) and chlorine (Cl) are removed as OF₂ and ClO.

Specifically, as shown in FIG. 16, step S49 includes two steps S49a and S49b. In step S49a, the plasma generator 6 puts plasma into the OFF state. At this time, the controller 12 can control the flow rate of Ar and the pressure in the chamber 2 to the same levels as those with the plasma purge in step S43.

Next, in step S49b, the controller 12 further opens the valve VB21, and supplies Ar and O₂ to the plasma generator 6. As a result, the plasma generator 6 generates O₂ plasma. The plasma generator 6 generates oxygen radicals through the O₂ plasma. The plasma generator 6 supplies the oxygen radicals to the chamber 2. Thus, the plasma purge is performed.

### <S50>

As shown in FIG. 15, the controller 12 performs an Ar purge. Specifically, as shown in FIG. 16, the controller 12 performs the Ar purge, for example, under the same conditions as those in step S44.

### <S51>

As shown in FIG. 15, the controller 12 performs a purge, using high-temperature H₂ and Ar. Specifically, as shown in FIG. 16, for example, the controller 12 performs the purge using high-temperature H₂ and Ar under the same conditions as those in step S45.

### <S52>

As shown in FIG. 15, the controller 12 checks whether the number of cleaning loops has reached a preset number.

If the number of cleaning loops has not reached the preset number (step S52_No), the controller 12 proceeds to step S13. On the other hand, if the number of cleaning loops has reached the preset number (step S52_Yes), the controller 12 proceeds to step S53.

Note that the controller 12 may change the time lengths of the reduction treatment process (step S14), the first etching process (step S41), and the second etching process (step S47) when repeating the cleaning loop.

### <S53>

As shown in FIG. 15, the controller 12 performs deposition of a coating film. A deposition condition of the coating film is the same as those in step S24 of the first embodiment.

### 4.5 Effects According to the Present Embodiment

With the configuration according to the present embodiment, the same effects as those of the first embodiment can be achieved.

Further, with the configuration according to the present embodiment, a plurality of etching processes using different halide gases containing different halogen elements can be performed. The binding energy with the element target element is different depending on each halogen element. Accordingly, etching characteristics such as the etching rate, the type of the etching by-product, and re-adhesion of the by-product are different depending on the halogen element contained in the cleaning gas. Thus, by executing a plurality of etching processes using halide gases containing different halogen elements, the cleaning process can be performed more effectively.

### 4.6 Modifications of the Fourth Embodiment

Next, a first modification and a second modification of the fourth embodiment will be described.

### 4.6.1 First Modification

First, the first modification of the fourth embodiment will be described. Although a case where the reduction treatment process is the same as that in FIG. 5 of the first embodiment has been described in the fourth embodiment, it is not limited to this. For example, the reduction treatment process may be the same as that described with reference to FIG. 10 of the third embodiment.

### 4.6.2 Second Modification

Next, the second modification of the fourth embodiment will be described. In the second modification, cases where the cleaning process (cleaning loop) includes three or more etching processes will be described.

First, a case where the cleaning process includes three etching processes will be described. More specifically, three cleaning gases A, B, and C containing different halogen elements are supplied to the plasma generator 6. Note that the halogen elements contained in the cleaning gases A, B, and C may be selected in ascending order of the binding energy to the etching target element, or may be selected in descending order. For example, iodine (I), bromine (Br), and chlorine (Cl) may be selected as the halogen elements contained in the cleaning gases A, B, and C, respectively. Further, in the cleaning process, the semiconductor manufacturing apparatus 1 successively performs a first etching process using the cleaning gas A, a second etching process using the cleaning gas B, and a third etching process using the cleaning gas C.

Next, a case where the cleaning process includes four etching processes will be described. More specifically, four cleaning gases A, B, C, and D containing different halogen elements are supplied to the plasma generator 6. Note that the halogen elements contained in the cleaning gases A, B, C, and D may be selected in ascending order of the binding energy to the etching target element, or may be selected in descending order. For example, iodine (I), bromine (Br), chlorine (Cl), and fluorine (F) may be selected as the halogen elements contained in the cleaning gases A, B, C, and D, respectively. Further, in the cleaning process, the semiconductor manufacturing apparatus 1 successively performs a first etching process using the cleaning gas A, a second etching process using the cleaning gas B, a third etching process using the cleaning gas C, and a fourth etching process using the cleaning gas D.

### 5. Fifth Embodiment

Next, a fifth embodiment will be described. In the fifth embodiment, two examples will be described as example configurations of a semiconductor manufacturing apparatus 1. In the description below, differences from the first to fourth embodiments are mainly explained.

### 5.1 First Example

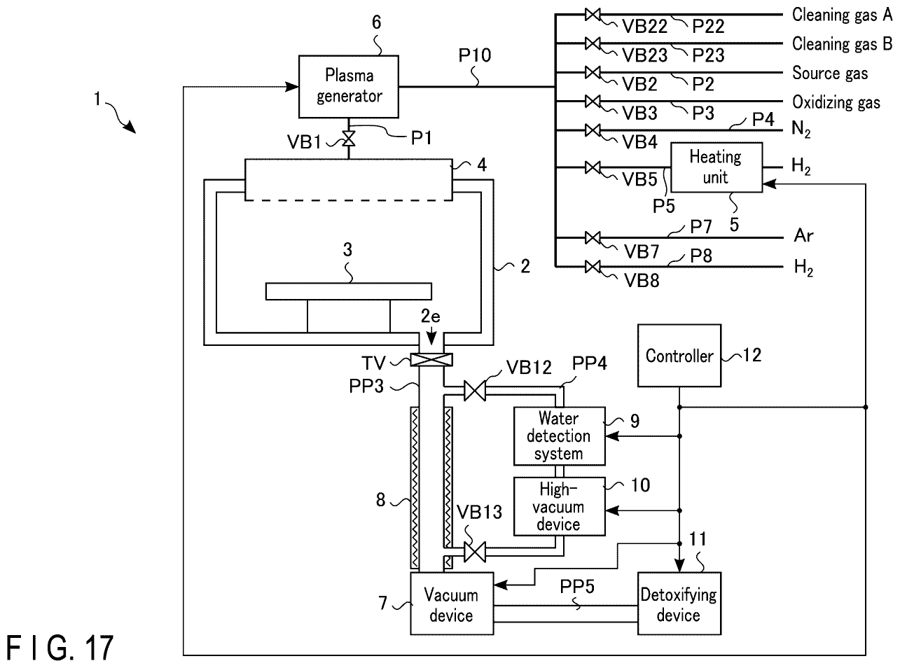

A first example of the fifth embodiment will be described with reference to FIG. 17. In the first example of the fifth embodiment, a case where the cleaning process described in the fourth embodiment is adopted in the semiconductor manufacturing apparatus 1 described with reference to FIG. 8 in the first example of the second embodiment will be described. FIG. 17 is a configuration diagram of the semiconductor manufacturing apparatus 1.

As shown in FIG. 17, in this example, a cleaning gas A, a cleaning gas B, a source gas, an oxidizing gas, N₂, high-temperature H₂, Ar, and H₂ are supplied to a plasma generator 6. That is, in this example, the source gas, the oxidizing gas, a reducing gas (H₂) and halide gases (the cleaning gases A and B) activated by the plasma generator 6, and the like are supplied to a chamber 2 (a showerhead 4) via a single supply pipe P1. The other aspects of the configuration are the same as those of the first example of the second embodiment in FIG. 8.

### 5.2 Second Example

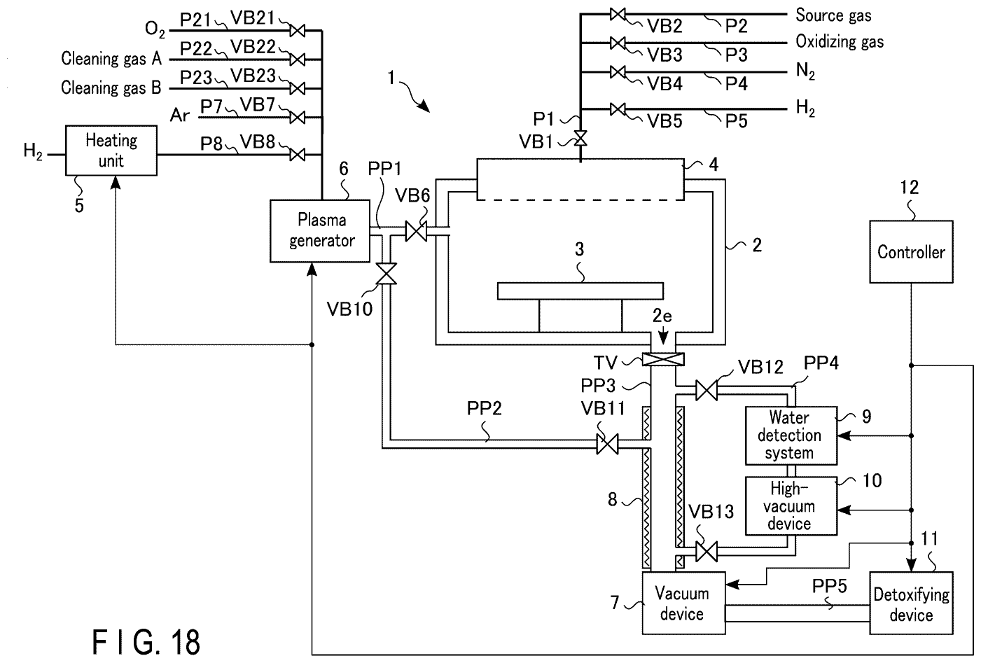

A second example of the fifth embodiment will be described with reference to FIG. 18. In the second example of the fifth embodiment, a case where the cleaning process described in the fourth embodiment is adopted in the semiconductor manufacturing apparatus 1 described with reference to FIG. 9 in the second example of the second embodiment will be described. FIG. 18 is a configuration diagram of the semiconductor manufacturing apparatus 1.

As shown in FIG. 18, in this example, O₂, a cleaning gas A, a cleaning gas B, Ar, and high-temperature H₂ are supplied to a plasma generator 6. The other aspects of the configuration are the same as those of the second example of the second embodiment in FIG. 9.

### 5.3 Effects According to the Present Embodiment

With the configuration according to the present embodiment, the same effects as those of the first to fourth embodiments can be achieved.

### 6. Modifications and the Like

According to above embodiments, a semiconductor manufacturing apparatus includes a chamber (2) that is used for deposition of an oxide film, a susceptor (3) that is provided in the chamber and on which a substrate is placed, at least a supply pipe (P1) that supplies a gas to the chamber, an exhaust pipe (PP3) that exhausts the gas from the chamber, and a controller (12) that is configured to control supply of each of a first source gas (In), an oxidizing gas (O₂), a reducing gas (H₂) activated by plasma, and a first halide gas (NF₃) activated by plasma to the chamber, and gas exhaust from the chamber.

Note that embodiments are not limited to the embodiments described above, and various modifications can be made to them.

Although cases where the semiconductor manufacturing apparatus 1 is a CVD apparatus of a conductive metal oxide film have been described in the above embodiments, the present invention is not limited to them. The semiconductor manufacturing apparatus 1 may be a film deposition apparatus other than a CVD apparatus, or may be an etching apparatus.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus comprising:
a chamber that is used for deposition of an oxide film;
a susceptor that is provided in the chamber, and on which a substrate is placed;
at least a supply pipe that supplies a gas to the chamber;
an exhaust pipe that exhausts the gas from the chamber; and
a controller that is configured to control supply of each of a first source gas, an oxidizing gas, a reducing gas activated by plasma, and a first halide gas activated by plasma to the chamber, and gas exhaust from the chamber.

2. The semiconductor manufacturing apparatus according to claim 1, wherein
the first source gas contains at least one element selected from Xe, Tl, F, Ag, Au, I, Cd, Br, Pd, Zn, Hg, Na, Rb, Cu, Cs, Bi, Li, In, Mg, Mn, Ni, and Ga.

3. The semiconductor manufacturing apparatus according to claim 1, wherein
the controller is further configured to control supply of a second source gas different from the first source gas to the chamber.

4. The semiconductor manufacturing apparatus according to claim 1, wherein
the first halide gas is at least one of NF₃, F₂, HF, SF₆, BCl₃, Cl₂, HCl, ClF₃, Br₂, HBr, I₂, and HI.

5. The semiconductor manufacturing apparatus according to claim 1, wherein
the supply of the reducing gas and the supply of the first halide gas are repeatedly performed.

6. The semiconductor manufacturing apparatus according to claim 1, further comprising
a water detection system that is coupled to the exhaust pipe, and detects water contained in an exhaust gas from the chamber.

7. The semiconductor manufacturing apparatus according to claim 1, further comprising
a heating device that heats hydrogen, wherein
the heated hydrogen is supplied to the chamber.

8. The semiconductor manufacturing apparatus according to claim 1, wherein
the controller is further configured to control supply of a second halide gas to the chamber, the second halide gas being activated by plasma and containing a halogen element different from the first halide gas.

9. The semiconductor manufacturing apparatus according to claim 8, wherein
the supply of the reducing gas, the supply of the first halide gas, and the supply of the second halide gas are repeatedly performed.

10. A method for manufacturing a semiconductor device, the method comprising:
carrying a substrate into a chamber having an inner wall;
supplying a first source gas and an oxidizing gas to the chamber to form an oxide film on the substrate, after the carrying the substrate into the chamber;
carrying the substrate, on which the oxide film is formed, out of the chamber;
supplying an activated reducing gas to the chamber, after the carrying the substrate out of the chamber; and
supplying an activated first halide gas to the chamber, after the supplying the activated reducing gas.

11. The method according to claim 10, wherein
the supplying the activated reducing gas and the supplying the activated first halide gas are repeatedly performed.

12. The method according to claim 10, wherein
after the supplying the activated reducing gas is started, water contained in an exhaust gas from the chamber is detected, and,
in a case where a detected value of water is greater than a preset value, the supplying the activated reducing gas is again performed.

13. The method according to claim 10, wherein
the oxide film adhering to the inner wall during a formation of the oxide film is reduced by the activated reducing gas.

14. The method according to claim 13, wherein
the reduced oxide film is etched using the activated first halide gas.

15. The method according to claim 10, wherein
the oxide film contains O and at least one element selected from Xe, Tl, F, Ag, Au, I, Cd, Br, Pd, Zn, Hg, Na, Rb, Cu, Cs, Bi, Li, In, Mg, Mn, Ni, and Ga.

16. The method according to claim 15, wherein
the oxide film is InGaZnO.

17. The method according to claim 14, wherein
the first halide gas is at least one of NF₃, F₂, HF, SF₆, BCl₃, Cl₂, HCl, ClF₃, Br₂, HBr, I₂, and HI.

18. The method according to claim 10, further comprising
supplying a heated hydrogen to the chamber, after the supplying the activated reducing gas.

19. The method according to claim 10, further comprising
supplying an activated second halide gas to the chamber, after the supplying the activated first halide gas, the second halide gas being containing a halogen element different from the first halide gas.

20. The method according to claim 19, wherein
the supplying the activated reducing gas, the supplying the activated first halide gas, and the supplying the activated second halide gas are repeatedly performed.
